(19) United States
(12) Patent Application Publication
(10) Pub. No.: US 2020/0123649 A1
(43) Pub. Date: Apr. 23, 2020

(54) OXIDATION PROCESSING MODULE, SUBSTRATE PROCESSING SYSTEM, AND OXIDATION PROCESSING METHOD

(71) Applicant: Tokyo Electron Limited, Tokyo (JP)

(72) Inventors: Kazunaga ONO, Nirasaki City (JP); Atsushi GOMI, Nirasaki City (JP); Kanto NAKAMURA, Nirasaki City (JP)

(21) Appl. No.: 16/653,944

(22) Filed: Oct. 15, 2019

(30) Foreign Application Priority Data
Oct. 19, 2018 (JP) 2018-197824

(51) Int. Cl. C23C 14/58; C23C 14/34; C23C 14/54

(52) U.S. Cl. CPC C23C 14/5853; C23C 14/541; C23C 14/34

(57) ABSTRACT

In an oxidation processing module, a stage on which a substrate having a metal film is mounted is provided and a cooling mechanism is provided to cool the stage to cool the substrate mounted on the stage to a temperature of 25° C. or lower. Further, a head unit has a facing surface disposed to face an upper surface of the stage and an oxidizing gas supply unit configured to supply oxidizing gas for oxidizing the metal film toward a gap between the facing surface and the upper surface of the stage, and a rotation driving unit is configured to rotate the head unit about a rotation axis intersecting with the upper surface of the stage.

### CROSS-REFERENCE TO RELATED APPLICATION

This application claims priority to Japanese Patent Application No. 2018-197824, filed on Oct. 19, 2018, the entire contents of which are incorporated herein by reference.

### TECHNICAL FIELD

The present disclosure relates to an oxidation processing module, a substrate processing system, and an oxidation processing method.

### BACKGROUND

The development of a magneto-resistive random access memory (MRAM) is in progress as a memory having excellent characteristics compared to those of a dynamic random access memory (DRAM) or the like. An MRAM manufacturing process may include a process of forming an insulating film with a ferromagnetic layer capable of changing a magnetization direction interposed therein.

International Patent Application Publication No. WO2015/064194 discloses a technique for oxidizing a metal in a processing chamber where a metal layer is formed by sputtering by supplying oxidizing gas toward the metal layer to form a metal oxide film of a magnetic tunnel junction (MTJ) element. Here, a temperature of the oxidizing gas is, e.g., in a range from 50° C. to 300° C.

The present disclosure provides an oxidation processing module capable of oxidizing a metal film under a condition in which a substrate is cooled to a temperature of 25° C. or lower, a substrate processing system including the oxidation processing module, and an oxidation processing method.

### SUMMARY

In accordance with an embodiment of the present disclosure, there is provided an oxidation processing module including: a stage on which a substrate having a metal film is mounted; a cooling mechanism configured to cool the stage to cool the substrate mounted on the stage to a temperature of 25° C. or lower; a head unit having a facing surface disposed to face an upper surface of the stage and an oxidizing gas supply unit configured to supply oxidizing gas for oxidizing the metal film toward a gap between the facing surface and the upper surface of the stage; and a rotation driving unit configured to rotate the head unit about a rotation axis intersecting with the upper surface of the stage.

### BRIEF DESCRIPTION OF THE DRAWINGS

The objects and features of the present disclosure will become apparent from the following description of embodiments, given in conjunction with the accompanying drawings, in which:

FIG. 1 is a plan view of a substrate processing system according to an embodiment;

FIG. 2 is a cross-sectional side view of a film forming module provided in the substrate processing system;

FIG. 3 is a cross-sectional side view of an oxidation processing module provided in the substrate processing system;

FIGS. 4A to 4D show a configuration of a head unit for supplying oxidizing gas in the oxidation processing module;

FIGS. 5A to 5C show simulation results of pressure distribution of oxygen gas when the oxidizing gas is supplied by using the head unit;

FIGS. 6A to 6C are graphs showing the pressure distribution of the oxygen gas;

FIG. 7 shows characteristic distribution of a resistance-area product (RA) value of a magnetic tunnel resistance element manufactured using the substrate processing system; and

FIG. 8 shows characteristic distribution of a magnetoresistance (MR) value of a substrate.

### DETAILED DESCRIPTION

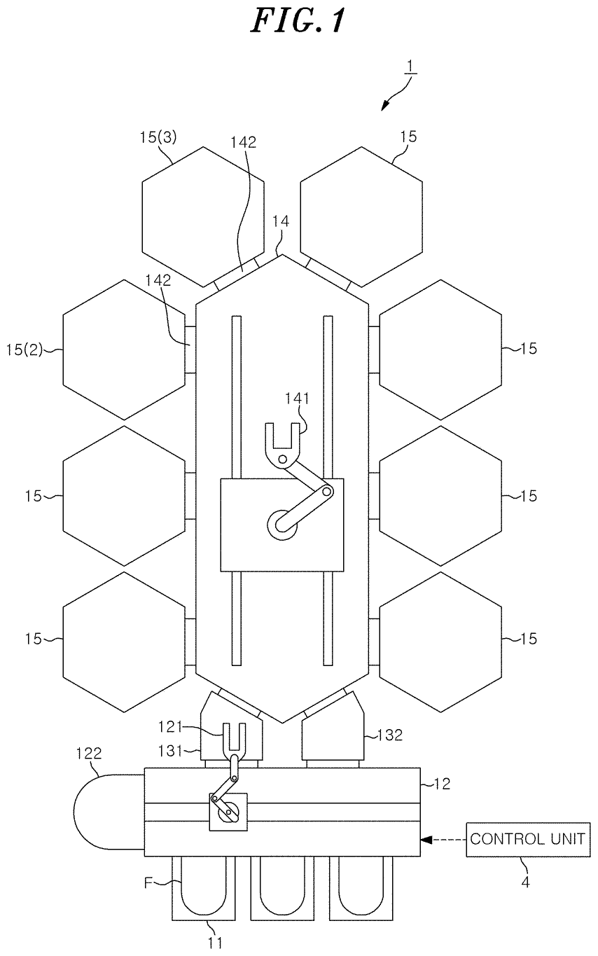

First, a configuration of a substrate processing system 1 including an oxidation processing module 3 according to an embodiment of the present disclosure will be described with reference to FIG. 1.

The substrate processing system 1 includes a plurality of load port 11, a loader module 12, load-lock modules 131 and 132, a transfer module 14, and a plurality of processing modules 15. In the substrate processing system 1 shown in FIG. 1, eight processing modules 15 are provided. However, the number of processing modules 15 may vary, if necessary.

The loader module 12 transfers a wafer W to be processed under an atmospheric pressure atmosphere. The load ports 11 are attached to the loader module 12. A transfer container F capable of accommodating multiple wafers W is mounted on each load port 11. A front opening unified pod (FOUP) may be used as the transfer container F. The wafer W is transferred between the transfer container F and the load-lock modules 131 and 132 disposed at a rear stage by a transfer arm 121 disposed in the loader module 12. In addition, an orienter 122 for adjusting a direction of the wafer W is disposed side by side with the loader module 12.

Each of the load-lock modules 131 and 132 switches an inner atmosphere thereof between an atmospheric pressure atmosphere and a vacuum atmosphere.

The transfer module 14 transfers the wafer W under a vacuum atmosphere. The transfer module 14 is connected to the load-lock modules 131 and 132 and the processing modules 15. The transfer module 14 transfers the wafer W between the load-lock modules 131 and 132 and the processing modules 15 using a transfer arm 141 provided therein.

For example, in an MRAM manufacturing process, the processing modules 15 include a chemical vapor deposition (CVD) module for forming a base film on a wafer, a film forming module for forming a multilayer film including a metal film and a magnetic film or a mask on an uppermost layer by sputtering, and the like.

Hereinafter, among the processing modules 15, a film forming module 2 capable of forming a metal film (a magnesium (Mg) film in the following example) by sputtering and an oxidation processing module 3 capable of performing an oxidation process while cooling the metal film formed by the film forming module 2 to a temperature of 25° C. or lower will be mainly described.

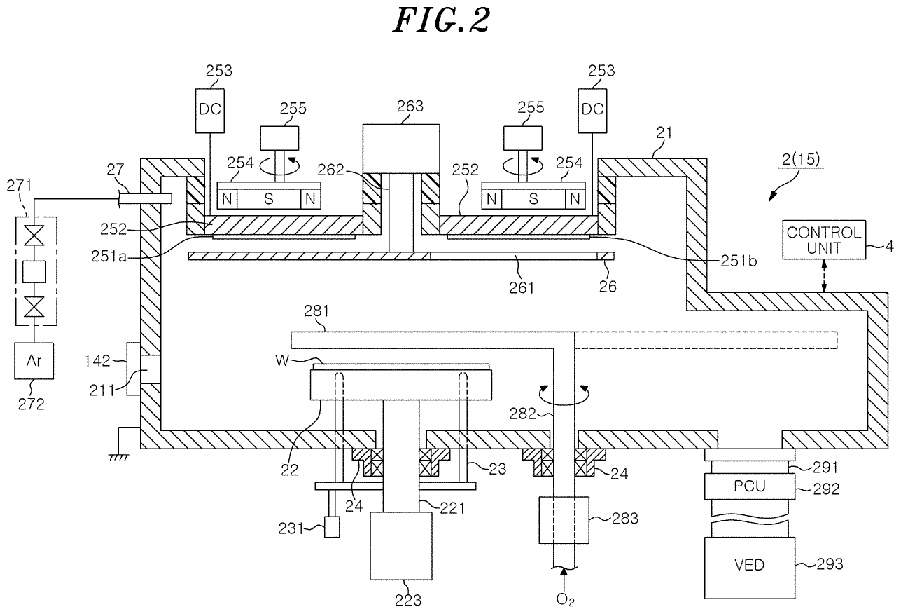

FIG. 2 shows a configuration example of the film forming module 2 that is one of the processing modules 15. For example, the film forming module 2 includes a vacuum chamber 21 made of a conductive material such as stainless steel or the like. The vacuum chamber 21 is grounded. Two target electrodes 252 formed in a circular shape in a plan view are disposed at a ceiling portion of the vacuum chamber 21. The target electrodes 252 are held while being electrically insulated from the vacuum chamber 21. Each of the target electrodes 252 is connected to a DC power supply unit (DC) 253. A negative DC voltage can be applied to the target electrodes 252 at the time of performing the sputtering.

Targets 251a and 251b, each of which is a source material for forming the metal film, are attached to the bottom surfaces of the target electrodes 252, respectively. The targets 251a and 251b are made of Mg that is a source material for forming a metal film on the wafer W. The targets 251a and 251b may be made of aluminum (Al), nickel (Ni), gallium (Ga), manganese (Mn), copper (Cu), silver (Ag), zinc (Zn), hafnium (Hf) or the like depending on a metal film to be formed on the wafer W.

A shutter 26 is disposed directly below the targets 251a and 251b. The shutter 26 is a circular plate having a size that covers projection areas of the targets 251a and 251b. The shutter 26 is suspended from the ceiling portion of the vacuum chamber 21 via a rotation axis 262. The rotation axis 262 is rotatable by a rotation mechanism 263. The shutter 26 is provided with one opening 261 that has a size slightly greater than the size of each of the targets 251a and 251b.

Therefore, when the opening 261 is positioned at a region facing one of the targets 251a and 251b, the other target 251b or 251a is covered with the shutter 26. Accordingly, when the sputtering is performed on one of the targets 251a and 251b, particles generated by the sputtering can be prevented from being adhered to the other target 251b or 251a.

Magnet arrays 254 are disposed at positions above the target electrodes 252, respectively. The magnet arrays 254 have a function of improving erosion uniformity of the targets 251a and 251b. The magnet arrays 254 include N-pole magnet groups and S-pole magnet groups arranged on a highly permeable material, e.g., an iron (Fe)-based body. The magnet arrays 254 are rotated or linearly moved at the rear surfaces of the targets 251a and 251b by driving mechanisms (DM) 255, respectively.

A stage 22 for horizontally mounting the wafer W is disposed at a position opposed to the targets 251a and 251b in the vacuum chamber 21. The stage 22 is connected to a driving mechanism 223 disposed below the vacuum chamber 21 through a rotation axis 221. The driving mechanism 223 has a function of rotating and vertically moving the stage 22. The stage 22 is vertically moved when the wafer W is transferred between the transfer arm 141 on the transfer module 14 side and lift pins 23. For example, the lift pins 23 are disposed at three locations to support the wafer W from the backside of the wafer W. The lift pins 23 are vertically moved by an elevation mechanism 231 to protrude beyond or retract below the stage 22.

The rotation axis 221 is connected to the driving mechanism 223 while extending through the bottom portion of the vacuum chamber 21. A sealing member 24 for maintaining the inside of the vacuum chamber 21 in an airtight state is disposed at a position where the rotation axis 221 penetrates through the vacuum chamber 21.

A heater (not shown) is incorporated in the stage 22, so that the wafer W can be heated to a temperature ranging from 25° C. to 400° C. during the sputtering.

A disk-shaped head unit 281 having a size greater than the wafer W is disposed inside the vacuum chamber 21. The head unit 281 is configured to be pivotably moved in a horizontal direction about a support column 282 disposed at one end portion thereof. The head unit 281 moves between a covered position where the wafer W is covered from an upper side thereof and a retreat position where the wafer W is retracted from the covered position. The support column 282 extends through the bottom portion of the vacuum chamber 21 and is rotatably supported by a rotation mechanism 283. A sealing member 24 for maintaining the inside of the vacuum chamber 21 in an airtight state is disposed at a position where the support column 282 penetrates through the vacuum chamber 21.

On the bottom surface of the head unit 281, multiple gas injection holes (not shown) for injecting oxidizing gas are arranged at equal intervals over the diameter of the head unit 281. When the oxidizing gas is supplied to the gas injection holes through a flow path (not shown) formed in the support column 282, the oxidizing gas is injected toward the stage 22. For example, the oxidizing gas includes oxygen gas and is used for oxidizing an Mg film (metal film) formed on the wafer W. A heater (not shown) constituting a heating unit is disposed in the head unit 281, so that a pre-heated oxygen gas can be injected.

A gas exhaust passage 291 is connected to the bottom portion of the vacuum chamber 21 and is also connected to a vacuum exhaust device (VED) 293 through a pressure control unit (PCU) 292. A gate valve 142 for opening and closing a loading/unloading port 211 for the wafer W is disposed on a side surface of the vacuum chamber 21. As shown in FIG. 1, the film forming module 2 is connected to the transfer module 14 through the gate valve 142.

An Ar gas supply line 27 for supplying an inert gas, e.g., Ar gas, for generating plasma into the vacuum chamber 21 is disposed at an upper portion of the sidewall of the vacuum chamber 21. The Ar gas supply line 27 is connected to an Ar gas supply source 272 through a gas control device group 271 such as a valve, a flow meter, and the like.

The film forming module 2 configured as described above is capable of forming an Mg film on the wafer W by sputtering and oxidizing the Mg film with oxygen gas supplied from the head unit 281. Since the stage 22 and the head unit 281 are provided with the heater (not shown) as described above, the pre-heated oxygen gas can be supplied to the wafer W that is heated in a range from 25° C. to 400° C. to perform the oxidation process.

Here, the degree of oxidation of the Mg film is determined by the amount of oxygen supplied to the Mg film and a reaction rate between Mg and oxygen. The reaction rate between Mg and oxygen changes depending on the temperature of the wafer W.

Therefore, it may be necessary to oxidize the Mg film at a temperature of 25° C. or lower, which is lower than the above-described temperature range.

It is desirable that the wafer W needs to be rotated with respect to the head unit 281 injecting the oxygen gas in order to uniformly oxidize the Mg film on the surface of the wafer W. The film forming module 2 shown in FIG. 2 is configured such that the stage 22 is rotated about the rotation axis 221, and thus is suitable for uniformly oxidizing the Mg film.

In order to set the temperature of the wafer W to a room temperature of 25° C. or lower, it is necessary to cool the wafer W using a cooling mechanism. The present inventors have found that it is difficult to rotate a stage provided with a cooling mechanism, compared to the stage 22 provided with the heater driven by electric power supplied thereto, because the cooling mechanism requires a coolant for heat transfer.

In this regard, it may be considered to rotate the head unit 281 with respect to the wafer W. Since, however, the targets 251a and 251b and the shutter 26 are disposed at the upper portion of the vacuum chamber 21, it is difficult to provide a rotation mechanism for the head unit 281 while avoiding interference with these devices.

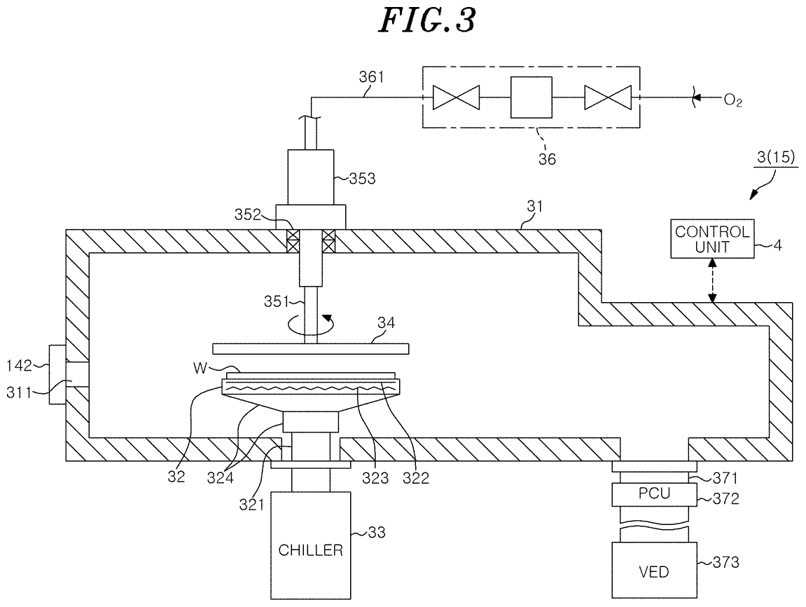

Therefore, the substrate processing system 1 in the present embodiment includes an oxidation processing module 3 for oxidizing the Mg film (metal film) under the condition that the wafer W is cooled to a temperature of 25° C. or lower. Hereinafter, the configuration of the oxidation processing module 3 will be described with reference to FIG. 3.

The oxidation processing module 3 has a configuration in which a stage 32 on which the wafer W having an Mg film is mounted, a chiller 33 for cooling the wafer W, a head unit 34 disposed at a position facing the wafer W mounted on the stage 32 and configured to inject oxygen gas (oxidizing gas) are provided in a vacuum chamber 31.

For example, the vacuum chamber 31 is made of a material such as stainless steel or the like, and the gate valve 142 for opening and closing a loading/unloading port 311 for the wafer W is disposed on a side surface thereof. As shown in FIG. 1, the oxidation processing module 3 is connected to the transfer module 14 through the gate valve 142.

As shown in FIG. 3, a gas exhaust passage 371 is connected to the bottom portion of the vacuum chamber 31, and is also connected to a vacuum exhaust device (VED) 373 via a pressure control unit (PCU) 372. The pressure control unit 372 and the vacuum exhaust device 373 constitute a pressure control mechanism for controlling an inner atmosphere of the vacuum chamber 31 to a vacuum atmosphere of 1.0×10−5 Pa to 1.0 Pa (corresponding to the range of high vacuum to medium vacuum).

The stage 32 on which the wafer W having the Mg film formed by the film forming module 2 is mounted is disposed in the vacuum chamber 31. The stage 32 is made of a material having high thermal conductivity, such as copper (Cu) or the like. The wafer W can be horizontally mounted on the stage 32. A dielectric layer (not shown) is formed on the upper surface of the stage 32, and a chuck electrode 322 is embedded in the dielectric layer. The dielectric layer and the chuck electrode 322 form an electrostatic chuck for attracting and holding the wafer W. Further, a heater 323 for controlling a temperature of the wafer W is disposed in the stage 32.

The stage 32 is provided with lift pins used for transferring the wafer W to and from the transfer arm 141 on the transfer module 14 side. However, the illustration of the lift pins is omitted.

Further, the stage 32 is provided with a gas supply line (not shown) for supplying helium (He) gas for heat transfer to the backside of the wafer W.

The chiller 33 is provided outside the vacuum chamber 31 to be positioned disposed below the stage 32. For example, the chiller 33 decreases a temperature of a cooling head 321 that is a low-temperature component by Gifford-McMahon cycle (G-M cycle) using helium (He) gas or the like. The cooling head 321 is formed in, e.g., a cylindrical shape. A thermally conductive member 324 is disposed between the cooling head 321 and the stage 32 to cool the stage 32 by thermal conduction.

The thermally conductive member 324 is made of a material having high thermal conductivity such as copper (Cu) or the like. In the example shown in FIG. 3, the thermally conductive member 324 includes an upper dish-shaped portion to be in contact with the entire bottom surface of the stage 32 and a lower disk-shaped portion to be in contact with the upper surface of the cooling head 321.

The chiller 33 and the thermally conductive member 324 constitute a cooling mechanism of the present embodiment. Further, the thermally conductive member 324 of the present embodiment serves as a support member for supporting the stage 32 from the bottom surface of the stage 32.

The chiller 33 has a function of cooling the wafer W mounted on the stage 32 to a temperature in a range from −223.15° C. (50K) to −25° C. In combination with the cooling of the chiller 33 and the heating of the temperature control heater 323, the wafer W on the stage 32 can be adjusted to a temperature in a range from −223.15° C. to 25° C.

As described above, in the case of cooling the wafer W mounted on the stage 32 in a structure in which the stage 32 is connected to the chiller 33, it is difficult to provide a rotation mechanism for rotating the stage 32 about the vertical axis extending through the center of the wafer W. Meanwhile, in order to uniformly oxidize the Mg film formed on the wafer W, it is required to rotate the wafer W with respect to the supply position of the oxidizing gas as described above.

Therefore, in the oxidation processing module 3 of the present embodiment, the head unit 34 for supplying oxidizing gas is disposed at a position facing the wafer W of the stage 32 and is rotated with respect to the wafer W.

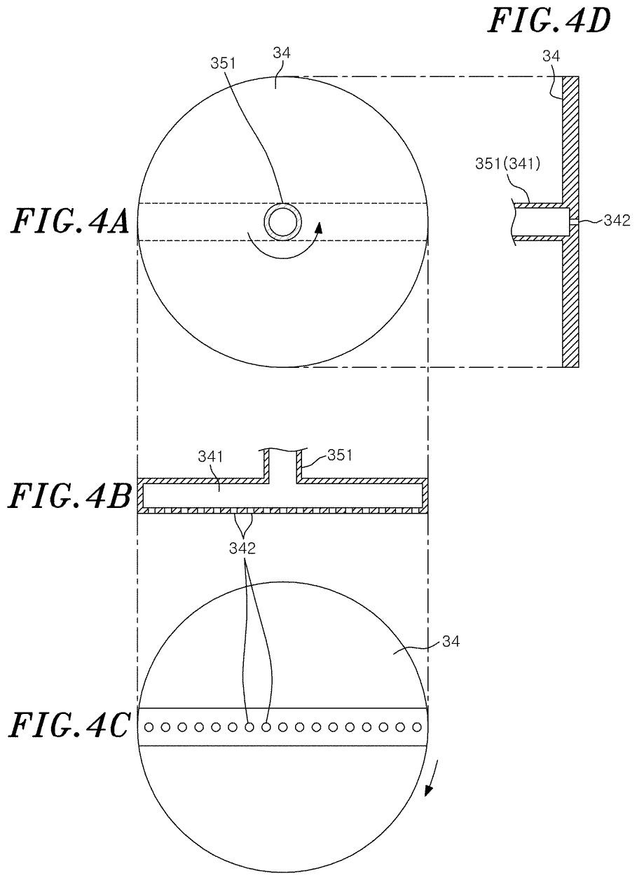

As shown in FIGS. 3 to 4D, for example, the head unit 34 is formed in a disk shape having a size greater than the wafer W. The bottom surface of the head unit 34 faces the stage 32. The head unit 34 is disposed above the stage 32 with a gap of 1 mm to 50 mm, e.g., 3 mm, between the bottom surface of the head unit 34 and the wafer W on the stage 32.

FIGS. 4A and 4C are a top view and a bottom view of the head unit 34, respectively. FIGS. 4B and 4D are cross-sectional side views of the head unit 34 viewed from directions intersecting with each other.

As shown in FIGS. 3 and 4A, a rotary tube 351 through which oxygen gas as oxidizing gas is supplied toward the head unit 34 is connected to the central position on the upper surface of the head unit 34, and the head unit 34 is suspended and supported by the rotary tube 351.

As shown in FIGS. 4B and 4C, an oxidizing gas flow path 341 is formed at the head unit 34 to allow the oxygen gas from the rotary tube 351 to flow along a diametrical direction of the head unit 34. The multiple gas injection holes 342 are formed in a line along the diametrical direction on the bottom surface of the oxidizing gas flow path 341. The oxidizing gas flow path 341 and the gas injection holes 342 constitute an oxidizing gas supply unit of the present embodiment.

As shown in FIG. 3, an upstream side of the rotary tube 351 extends upward in a vertical direction, and an upper end of the rotary tube 351 extends through the ceiling portion of the vacuum chamber 31. The rotary tube 351 is connected to a gas flow path 361. The gas flow path 361 is connected to an oxygen gas supply source (not shown) through a gas control device group 36 such as a valve, a flow meter, and the like. A sealing member 352 for maintaining the inside of the vacuum chamber 31 in an airtight stage is disposed at a position where the rotary tube 351 extends through the vacuum chamber 31.

A rotation mechanism (rotation driving unit) 353 for rotating the rotary tube 351 around the vertical axis is disposed at the upper end side of the rotary tube 351 where the rotary tube 351 penetrates through the ceiling portion of the vacuum chamber 31. By rotating the rotary tube 351, the head unit 34 suspended from the rotary tube 351 can be rotated about the vertical axis intersecting with the upper surface of the stage 32. The rotary tube 351 rotates at a speed of rotating the head unit 34 at least once during the oxidation of the Mg film. The rotation mechanism 353 may serve as an elevation mechanism for vertically moving the position of the head unit 34.

As shown in FIGS. 1 to 3, the substrate processing system 1 including the film forming module 2, the oxidation processing module 3, and other processing modules 15 is provided with a control unit 4 having a computer that stores a program. This program has a group of steps for transmitting control signals to the respective components of the substrate processing system 1 to control operations of the respective components and executing processes on the wafer W. Based on this program, the control for sequentially transferring the wafer W to be processed to the processing modules 15, the control for forming an Mg film on the wafer W in the film forming module 2, the control for oxidizing the Mg film in the oxidation processing module 3, and the like are executed. The program is installed in the control unit 4 from a storage medium such as a hard disk, a compact disk, a magneto-optical disk, a memory card, or the like.

The operation of the film forming module 2 configured as described above will be described.

First, when the transfer container F is mounted on the load port 11, the cover of the transfer container F is removed by an opening/closing mechanism (not shown) disposed in the loader module 12. Thereafter, the wafer W to be processed is taken out by the transfer arm 121, and the position of the wafer W is adjusted and aligned by the orienter 122. Then, the wafer W is loaded into one of the load-lock modules 131 and 132.

The inner atmosphere of the load-lock module 131 or 132 where the wafer W is accommodated is switched from an atmospheric pressure atmosphere to a vacuum atmosphere. Then, the wafer W in the load-lock module 131 or 132 is transferred into the transfer module 14 by the transfer arm 141. Next, the wafer is sequentially transferred to the processing modules 15 and subjected to predetermined processings based on a preset transfer schedule. Accordingly, a base film or a multilayer film including a metal film, a magnetic film, or the like is formed on the wafer W.

In order to form an Mg oxide film during the formation of the multilayer film on the wafer W, the wafer W to be processed is loaded into the film forming module 2.

When the wafer W is transferred from the transfer arm 141 to the stage 22 through the lift pins 23, the transfer arm 141 is retracted from the vacuum chamber 21 and the gate valve 142 is closed. Then, Ar gas is supplied from the Ar gas supply line 27 into the vacuum chamber 21, and the vacuum chamber 21 is evacuated by the vacuum evacuation device 293. At this time, the inner atmosphere of the vacuum chamber 21 is controlled to a vacuum atmosphere of, e.g., 1.0×10−2 Pa to 1.0 Pa, by the pressure control unit 292.

Next, the stage 22 is rotated at a rotational speed of, e.g., 1 rpm to 120 rpm, and the wafer W is heated to a temperature of 25° C. to 400° C. by a heater (not shown). As indicated by a dashed line in FIG. 2, the head unit 281 is retreated from a position above the stage 22.

Thereafter, one of the magnet arrays 254 disposed above the target 251a or 251b that is subjected to the film formation is driven, and a DC voltage of, e.g., 300 V, is applied to the target electrode 252 disposed below the corresponding magnet array 254. Then, the shutter 26 is rotated so that the opening 261 is positioned below the target 251a or 251b that is subjected to the film formation.

Due to the above-described operations, the plasma of Ar gas is generated below the corresponding target electrode 252, and the target 251a or 251b subjected to the film formation (the target 251b in the example shown in FIG. 2) is sputtered. Mg particles generated by the sputtering are adhered to the surface of the wafer W on the stage 22, thereby forming an Mg film. In the case of forming an Mg film of several angstroms, the sputtering is performed for several seconds to several tens of seconds.

The sputtering is performed for a preset period of time. When an Mg film of a desired film thickness is formed, the voltage application to the target electrode 252, the Ar gas supply, and the driving of the magnet array 254 are stopped. Further, the shutter 26 is rotated so that the opening 261 is moved away from the position below the targets 251a and 251b.

Next, the Mg film formed on the surface of the wafer W is oxidized. Whether the oxidation process will be performed in the film formation module 2 or the oxidation processing module 3 is selected depending on the temperature of the wafer W when the oxidation process is performed.

For example, when the oxidation process is performed by heating the wafer W to a temperature in a range from 25° C. to 400° C., the oxidation process is continuously performed in the film forming module 2.

In this case, if necessary, a pressure in the vacuum chamber 31 is adjusted to a range of high vacuum to medium vacuum, and the support column 282 is rotated to move the head unit 281 to a position above the wafer W on the stage 22. The stage 22 is rotated at a rotation speed of, e.g., 1 rpm to 120 rpm. The rotation speed of the stage 22 is set so that the wafer W can rotate at least once during the oxidation process. The wafer W is heated to a temperature in a range from 25° C. to 400° C. by a heater (not shown).

Then, oxygen gas is supplied to the head unit 281 through the flow path formed in the support column 282. The oxygen gas preheated by the heater (not shown) in the head unit 281 is injected toward the surface of the heated rotating wafer W, and is uniformly supplied toward the Mg film. By supplying the oxygen gas, the Mg film on the surface of the wafer W is oxidized to an MgO film. The oxidation of the Mg film is executed for a preset period of time depending on the thickness of the Mg film or the heating temperature of the wafer W.

In the film forming module 2, the film formation of the Mg film by sputtering and the oxidation of the Mg film using the head unit 281 may be alternately performed multiple times.

In the case of performing the oxidation process by cooling the wafer W to a temperature of 25° C. or lower, the oxidation process is performed in the oxidation processing module 3.

Specifically, the wafer W having the Mg film is unloaded from the film forming module 2 and transferred by the transfer arm 141 in a reverse order to that used in the loading operation.

Next, the gate valve 142 of the oxidation processing module 3 is opened, and the wafer W is loaded into the vacuum chamber 31 through the loading/unloading port 311. When the wafer W is transferred from the transfer arm 141 to the stage 32 through the lift pins (not shown), the transfer arm 141 is retracted from the vacuum chamber 31 and the gate valve 142 is closed. Then, the vacuum chamber 31 is evacuated by the vacuum exhaust device 373. At this time, the inner atmosphere of the vacuum chamber 31 is adjusted to a vacuum atmosphere of 1.0×10⁻⁵ Pa to 1.0 Pa by the pressure control unit 372.

Next, the wafer W on the stage 32 is cooled to a temperature in a range from −223.15° C. to 25° C. by the chiller 33 or by combination of the cooling of the chiller 33 and the heating of the heater 323.

The head unit 34 disposed to face the wafer W on the stage 32 is rotated at a rotational speed of, e.g., 1 rpm to 120 rpm. The rotational speed of the head unit 34 is set so that the head unit 34 rotates at least once during the oxidation process.

Then, oxygen gas is supplied to the oxidizing gas flow path 341 through the rotary tube 351, and is injected toward the wafer W. Accordingly, the oxygen gas is injected from the rotating head unit 34 toward the surface of the wafer W cooled on the stage 32. By supplying the oxygen gas, the Mg film on the surface of the wafer W is oxidized to an MgO film. The oxidation of the Mg film is executed for a preset period of time depending on the thickness of the Mg film or the heating temperature of the wafer W.

Since the gas injection holes 342 are arranged in a line along the diametrical direction as shown in FIG. 4C, the oxygen gas is supplied from the bottom surface of the head unit 34 toward a substantially linear region. By rotating the head unit 34, the entire surface of the wafer W mounted on the stage 32 can be scanned by the linear region to which the oxygen gas is supplied.

The oxygen gas supplied onto the surface of the wafer W flows toward the space on both sides of the linear region where the gas injection holes 342 are not arranged. Due to this gas flow, generation of an oxygen gas stagnation region in the gap between the head unit 34 and the wafer W is suppressed. Accordingly, the oxidation process can be more uniformly performed.

When the entire surface of the wafer W is scanned by the oxygen gas supply region as described above, the gas injection holes 342 are not necessarily arranged over the diameter of the head unit 34. For example, the gas injection holes 342 may be arranged over a region longer than the radius of the head unit 34. The gas injection holes 342 do not necessarily have a small hole shape, and may have a slit shape.

Further, even when the inner atmosphere of the vacuum chamber 31 is set to the vacuum atmosphere, it is possible to generate a region where the pressure of the oxygen gas is relatively high by providing the disk-shaped head unit 34 above the wafer W with a gap of about 1 to 50 mm therebetween. Accordingly, the oxygen gas injected from the gas injection holes 342 is prevented from being scattered and lost to the surroundings immediately, thereby sufficiently oxidizing the Mg film.

When the oxidation process in the oxidation processing module 3 is completed, the wafer W having the MgO film is unloaded from the vacuum chamber 31 and transferred by the transfer arm 141 in a reverse order to that used in the loading operation.

In the case when the Mg film formation by sputtering and the oxidation process under the condition of cooling the wafer W are performed alternately multiple times, the wafer W is repeatedly transferred between the film formation module 2 and the oxidation processing module 3.

When an MgO film having a desired thickness is formed, the wafer W is sequentially transferred to and processed in the processing modules 15 to form a multilayer film having a preset structure, and a mask is finally formed on the uppermost layer.

Then, the wafer W having the multilayer film is transferred to the loader module 12 through the load-lock module 131 or 132 and returned to the original transfer container F.

The technique of the present disclosure has the following effects. The wafer W mounted on the stage 32 is cooled to a temperature of 25° C. or lower by the chiller 33, and the head unit 34 for supplying oxygen gas is configured to be rotated. Accordingly, in-plane uniformity of the oxidation process on the wafer W can be achieved while solving the problem of the difficulty in providing a rotation mechanism on the stage 32 side.

Here, the oxidation processing module 3 is not necessarily used as a dedicated module for performing an oxidation process under the condition of cooling the wafer W to 25° C. or lower. For example, the head unit 34 of the present disclosure may be provided at a cooling module that has been conventionally used in the film forming processing system and is provided with the stage 32 connected to the chiller 33 to cool the wafer W. In this example, the cooling module (the oxidation processing module 3) can perform the oxidation process and the cooling of the wafer W, and also can suppress an increase in a footprint of the substrate processing system 1.

In addition, it is not necessary to perform the oxidation process in the film forming module 2. For example, the chiller 33 and the heater 323 may be switched to be used in the oxidation processing module 3. In this case, the oxidation process can be performed at a wider temperature range of −223.15° C. to +400° C. In this example, it is not necessary to install the head unit 281 in the film forming module 2 and, thus, a retreat region for the head unit 281 is not required. Accordingly, the film forming module 2 can be scaled down.

In addition, the oxidizing gas supply unit may not have a configuration in which the gas injection holes 342 are arranged in a line along the diametrical direction of the head unit 34. As long as the problem such as stagnation of oxygen gas does not occur, the gas injection holes 342 may be distributed over the entire bottom surface of the head unit 34, as in the case of a shower head, for example.

Alternatively, it may be possible to form one gas injection hole 342 at the central portion of the head unit 34.

The head unit 34 may not be a disk-shaped plate greater than the wafer W. For example, a head unit 34 smaller than the diameter of the wafer W may be used to allow the oxygen gas injected from the gap between the wafer W and the head unit 34 to flow along the wafer W and reach the peripheral portion of the wafer W.

The rotary tube 351 may be connected to a position deviated from the center of the disk-shaped head unit 34, and the wafer W may be rotated at an eccentric position.

The oxidizing gas used for the oxidation of the Mg film (metal film) is not limited to oxygen gas, and may be, e.g., ozone gas.

The cooling mechanism for cooling the wafer W is not limited to the chiller 33. For example, the wafer W may be cooled by providing a coolant flow path in the stage 32 and circulating a coolant cooled at the outside therethrough.

The above-described embodiments are considered to be illustrative in all aspects and not restrictive. The above-described embodiments may be omitted, replaced, or changed variously without departing from the scope and the gist of the following claims.

### TEST EXAMPLES

(Simulation 1)

A simulation model between the wafer W and the bottom surface of the head unit 34 was created based on the oxidation processing module 3 configured as described with reference to FIGS. 3 to 4D, and the flow of the oxygen gas on the surface of the wafer W was calculated.

### A. Simulation Conditions

A fluid analysis software was used to calculate pressure distribution in the space between the wafer W and the head unit 34 in the case of supplying oxygen gas while sufficiently rotating the head unit 34. The wafer W has a diameter of 300 mm. Several tens of gas injection holes 342 each having a diameter of several mm, are formed in a line in the head unit 34.

### Test Example 1

In-plane pressure distribution of the oxygen gas on the wafer W was calculated in the case of setting an ambient pressure (a pressure in the vacuum chamber 31) to medium vacuum and supplying oxygen gas having a concentration of 100% at a flow rate of 1000 sccm.

### Test Example 2

In-plane pressure distribution of the oxygen gas on the wafer W was calculated under the same conditions as those in the test example 1 except that the flow rate of the oxygen gas was set to 100 sccm.

### Test Example 3

In-plane pressure distribution of the oxygen gas on the wafer W was calculated in the case of setting the ambient pressure (the pressure in the vacuum chamber 31) to high vacuum and supplying the oxygen gas at a flow rate of 1 sccm.

### B. Simulation Results

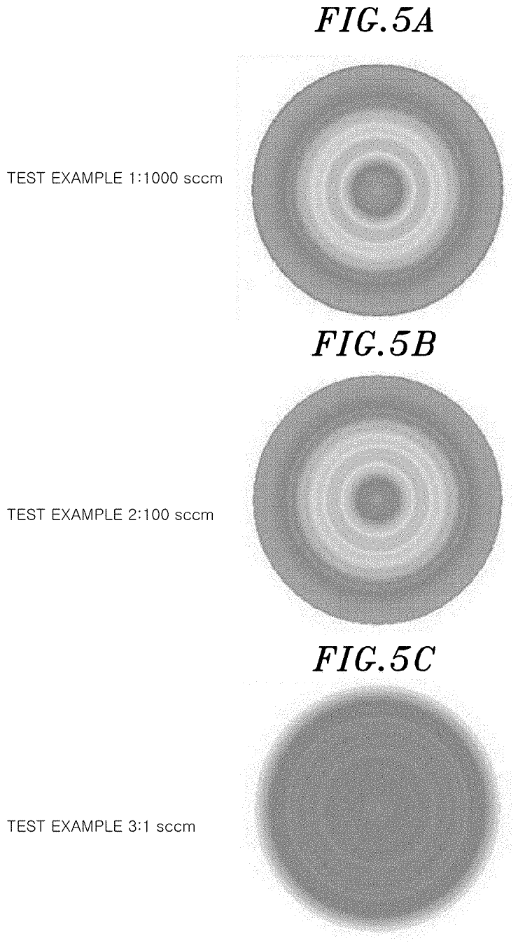

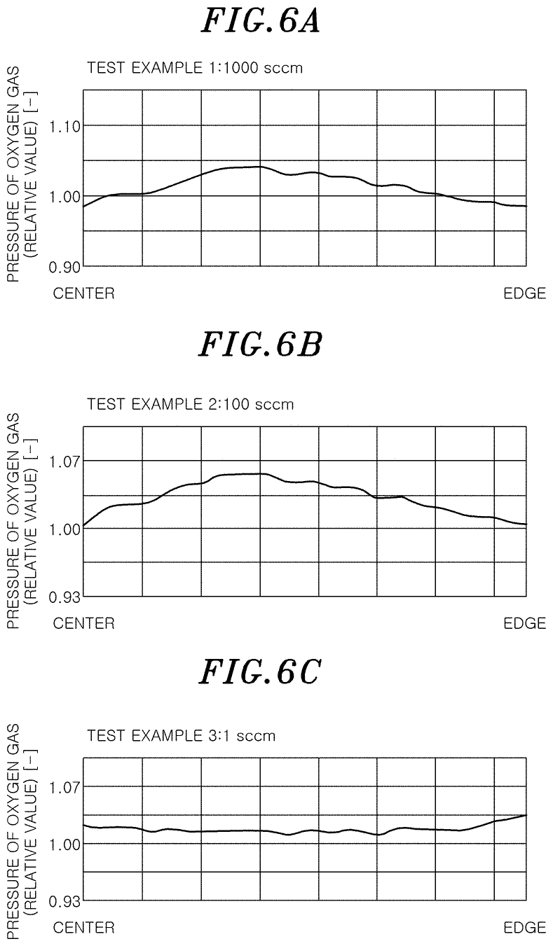

FIGS. 5A to 5C show the in-plane pressure distribution of the wafer W obtained in the test examples 1 to 3. FIGS. 6A to 6C are the graphs showing the pressure distribution in the radial direction. The horizontal axis and the vertical axis in FIGS. 6A to 6C represent the position on the wafer W in the radial direction and the pressure of the oxygen gas (normalized relative value), respectively.

Although the actual calculation results are illustrated in different colors depending on the pressure of the oxygen gas, they are displayed in grayscale in FIGS. 5A to 5C due to limitation of illustration. According to the results shown in FIGS. 5A to 5C, the concentric pressure distribution that is rotationally symmetrical along the circumferential direction is generated on the surface of the wafer W by supplying the oxygen gas using the rotating head unit 34.

Therefore, FIGS. 6A to 6C show the oxygen gas pressure distribution viewed along any radial direction of the wafer W.

In the above calculation results, 1σ, i.e., standard deviation of the pressure distribution of the oxygen gas on the surface of the wafer W, was calculated. According to the above calculation results, 1σ was 1.9% in the test example 1, 1.8% in the test example 2, and 0.7% in the test example 3, which indicate that the variation in the pressure distribution can be suppressed.

(Simulation 2)

In-plane physical property distribution of a magnetic tunnel resistance element on the wafer W was measured. The magnetic tunnel resistance element was manufactured using the substrate processing system 1 including the film forming module 2 shown in FIG. 2 and the oxidation processing module 3 shown in FIG. 3.

### A. Simulation Conditions

### Test Example 4

As the physical properties for evaluating the resistance element, a resistance-area product (RA) and a magnetoresistance (MR) were measured. Accordingly, in-plane distribution of the physical property values was evaluated.

### B. Simulation Results

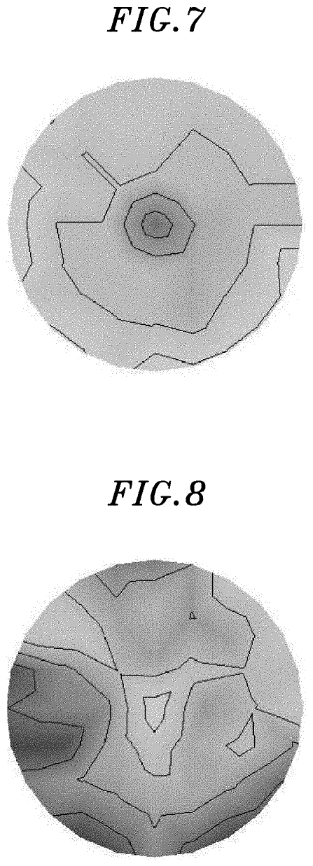

FIG. 7 shows the in-plane distribution of the RA value in the test example 4. FIG. 8 shows the in-plane distribution of the MR value in the test example 4. Although they are actually displayed in different colors depending on the physical values, they are displayed in grayscale patterns in FIGS. 7 and 8 due to limitation of illustration.

Non-uniform distribution that the physical property values change abruptly in a narrow region was not observed in both of the RA value shown in FIG. 7 and the MR value shown in FIG. 8. Further, 1σ that is the standard deviation of the RA value and the MR value in the test example 4 was calculated. 1σ of the RA value was 1.3%, and 1σ of the MR value was 1.0%, which was satisfactory.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. An oxidation processing module comprising:
a stage on which a substrate having a metal film is mounted;
a cooling mechanism configured to cool the stage to cool the substrate mounted on the stage to a temperature of 25° C. or lower;
a head unit having a facing surface disposed to face an upper surface of the stage and an oxidizing gas supply unit configured to supply oxidizing gas for oxidizing the metal film toward a gap between the facing surface and the upper surface of the stage; and
a rotation driving unit configured to rotate the head unit about a rotation axis intersecting with the upper surface of the stage.

2. The oxidation processing module of claim 1, wherein the oxidizing gas supply unit includes one or more gas injection holes that are arranged at a region at which the oxidizing gas supplied from the gas injection holes is capable of scanning the entire surface of the substrate mounted on the stage while rotating the head unit.

3. The oxidation processing module of claim 1, wherein the cooling mechanism includes a chiller having a low-temperature component that absorbs heat and a thermally conductive member disposed between the stage and the low-temperature component to cool the stage by thermal conduction.

4. The oxidation processing module of claim 2, wherein the cooling mechanism includes a chiller having a low-temperature component that absorbs heat and a thermally conductive member disposed between the stage and the low-temperature component to cool the stage by thermal conduction.

5. The oxidation processing module of claim 3, wherein the thermally conductive member is a support member configured to support the stage from a bottom surface of the stage 32.

6. The oxidation processing module of claim 4, wherein the thermally conductive member is a support member configured to support the stage from a bottom surface of the stage 32.

7. The oxidation processing module of claim 1, wherein the stage has an electrode forming an electrostatic chuck to hold the substrate.

8. The oxidation processing module of claim 2, wherein the stage has an electrode forming an electrostatic chuck to hold the substrate.

9. The oxidation processing module of claim 1, wherein the stage has therein a heater configured to control a temperature of the substrate.

10. The oxidation processing module of claim 2, wherein the stage has therein a heater configured to control a temperature of the substrate.

11. The oxidation processing module of claim 1, wherein the stage is disposed in a processing module including a pressure control mechanism configured to control an internal pressure of the processing module to a vacuum atmosphere of high vacuum to medium vacuum.

12. The oxidation processing module of claim 2, wherein the stage is disposed in a processing module including a pressure control mechanism configured to control an internal pressure of the processing module to a vacuum atmosphere of high vacuum to medium vacuum.

13. A substrate processing system comprising:
a load port configured to mount a substrate transfer container to load and unload a target substrate to and from the substrate transfer container under an atmospheric pressure atmosphere;
a transfer module configured to transfer the substrate under a vacuum atmosphere;
a load-dock module disposed between the load port and the transfer module to switch a substrate transferring atmosphere between the atmospheric pressure atmosphere and the vacuum atmosphere;
one or more film forming modules connected to the transfer module through a gate valve and configured to form a metal film on the target substrate by sputtering; and
the oxidation processing module described in claim 1 that is connected to the transfer module through a gate valve.

14. A substrate processing system comprising:
a load port configured to mount a substrate transfer container to load and unload a target substrate to and from the substrate transfer container under an atmospheric pressure atmosphere;
a transfer module configured to transfer the substrate under a vacuum atmosphere;
a load-dock module disposed between the load port and the transfer module to switch a substrate transferring atmosphere between the atmospheric pressure atmosphere and the vacuum atmosphere;
one or more film forming modules connected to the transfer module through a gate valve and configured to form a metal film on the target substrate by sputtering; and
the oxidation processing module described in claim 2 that is connected to the transfer module through a gate valve.

15. An oxidation processing method comprising:
mounting a substrate having a metal film on a stage;
cooling the stage to cool the substrate mounted on the stage to a temperature of 25° C. or lower; and
by using a head unit having a facing surface disposed to face an upper surface of the stage and an oxidizing gas supply unit configured to supply oxidizing gas, oxidizing the metal film by supplying the oxidizing gas to a gap between the facing surface and the upper surface of the stage while rotating the head unit about a rotation axis intersecting with the upper surface of the stage.

16. The oxidation processing method of claim 15, wherein said oxidizing the metal film is performed under a vacuum atmosphere of high vacuum to medium vacuum.

17. The oxidation processing method of claim 15, further comprising:
forming the metal film on the substrate by sputtering before the substrate is mounted on the stage.

18. The oxidation processing method of claim 16, further comprising:
forming the metal film on the substrate by sputtering before the substrate is mounted on the stage.
